(19) United States
(12) Patent Application Publication
(10) Pub. No.: US 2025/0055255 A1
(43) Pub. Date: Feb. 13, 2025

(54) AN IMPROVED FREQUENCY COMB LASER DEVICE

(71) Applicant: Munster Technological University (MTU), Bishopstown, Cork (IE)

(72) Inventors: Ganga Chinna Rao Devarapu, Bishopstown, Cork (IE); William Whelan-Curtin, Garryoughra, Mogeely, Cork (IE); Frank SMYTH, Castleknock (IE)

(21) Appl. No.: 18/722,460

(22) PCT Filed: Dec. 21, 2022
(86) PCT No.: PCT/EP2022/087379

§ 371 Date: Jun. 20, 2024

(30) Foreign Application Priority Data
Dec. 21, 2021 (GB) 2118610.1

(51) Int. Cl. H01S 5/14; G02F 1/35; G02F 1/365; G02F 1/39; H01S 5/026; H01S 5/11; H01S 5/50

(52) U.S. Cl. CPC H01S 5/142; G02F 1/3536; G02F 1/365; G02F 1/39; H01S 5/026; H01S 5/11; H01S 5/5054

(57) ABSTRACT

The invention provides a frequency comb laser device comprising a laser cavity having an optical gain material for coupling light to a waveguide comprising a dispersive material; a reflector at the end of the optical gain material and a resonant mirror at the other; where the resonant mirror comprises an on-chip waveguide coupled to a fabry perot cavity formed by one or more photonic crystal reflectors, such that lasing operation is sustained with the laser cavity. The invention makes it possible to improve the control of the dispersion of a frequency comb source through the use of a PhC structure of the present invention in combination with or without other dispersion control mechanisms.

### FIELD

The present disclosure is directed towards improvements in the generation of frequency combs for a frequency comb laser.

### BACKGROUND

A comb laser is a special type of laser that produces an output that consists of equally spaced discrete frequencies. This results in a laser that has an output which looks like a comb when viewed in the frequency domain. As such, the output of a comb laser is commonly referred to as a frequency comb. Frequency combs have many applications, for example they are commonly used in the fields of e.g. spectroscopy, atomic clocks, frequency synthesis, precision-GPS, optical metrology, telecommunications, etc.

Traditionally, comb lasers have been made using mode-locked lasers. In these mode-locked lasers, a series of optical pulses is produced. Each pulse is separated from the next in time domain by the round-trip time of the laser cavity. The resultant pulse train has a spectrum that approximates a series of Dirac delta functions separated by the repetition rate (the inverse of the round-trip time) of the laser. This series of sharp spectral lines is called a frequency Dirac comb.

Comb lasers can be realised using optical fibres with Distributed Bragg Reflectors deposited on the ferrules. Such systems are limited by the materials and devices available, namely the optical fibre has a low nonlinearity and provides low refractive index contrast. An example of such a type of comb laser is described in European Publication Number EP3 479 443. Fibre lasers are large and costly which limit their scope for the deployment.

A more recent technique for obtaining a frequency comb is through the use of cascaded four-wave mixing based on the Kerr-nonlinearity. Four-wave mixing is a process where intense light at three frequencies interact to produce light at a fourth frequency. If the three frequencies are part of a perfectly spaced frequency comb, then the fourth frequency is mathematically required to be part of the same comb as well.

Unlike a mode-locked comb laser, these two types of comb lasers do not depend on the gain medium of the pump laser. Instead, they rely on the nonlinear properties of the waveguides or micro-resonators. As a result, frequency combs can in principle be generated around any desired pump frequency.

Kerr-nonlinearity based frequency combs (which are also referred in the art as Kerr frequency combs) are highly popular as they provide large mode spacing (10 GHz to 1 THz) due to their free spectral range (FSR) when compared to mode locked lasers (10 MHz to 1 GHZ). Most on-chip micro-resonators used to date for Kerr frequency comb generation are either micro-rings or micro-disks. The symmetrical nature of these circular resonators is useful for obtaining large Q-factors. Large Q-factors in turn facilitate the exploitation of non-linearities in the laser cavity medium to achieve four-wave mixing, a key process required for the comb formation.

The overall dispersion of the cavity (which is also known in the art as an optical resonator) of the laser is a major factor in determining the duration of the pulses emitted by the laser. A pair of prisms can be arranged to produce net negative dispersion, which can be used to balance the usually positive dispersion of the laser medium. Diffraction gratings can also be used to produce dispersive effects; these are often used in high-power laser amplifier systems. Recently, an alternative to prisms and gratings has been developed: chirped mirrors. These dielectric mirrors are coated so that different wavelengths have different penetration lengths, and therefore different group delays. The coating layers can be tailored to achieve a net negative dispersion. However, chirped mirrors of this type are not compatible with integration on chip.

Despite their popularity, the prior art comb lasers described above (i.e. those based on circular resonators) only allow limited control on dispersion. Dispersion control is important to ensure evenly spaced resonances and efficient four wave mixing.

The present disclosure is directed towards solving these and other problems through the provision of a comb source to provide better dispersion control.

### SUMMARY OF THE INVENTION

According to the invention there is provided, as set out in the appended claims, a frequency comb laser device comprising: a laser cavity having an optical gain material for coupling light to a waveguide comprising a dispersive material; a reflector at the end of the optical gain material and a resonant mirror at the other; where the resonant mirror comprises an on-chip waveguide coupled to a fabry perot cavity formed by one or more photonic crystal reflectors, such that lasing operation is sustained with the laser cavity.

The invention provides a novel on-chip FP cavity that yields high-Q longitudinal modes due to the highly reflecting photonic crystal structures (PhCs) at the end of the cavity. Coupling to the FP cavity from an on-chip waveguide provides a highly effective mechanism for exciting the modes of the FP cavity, which minimises losses. This configuration also operates as a resonant mirror providing the optical feedback into a reflective semiconductor optical amplifier required for lasing.

In one embodiment the laser cavity is configured to be in resonance with one of the modes supported by the Fabry Perot cavity, such that the light stored within the Fabry-Perot cavity comprises an optical density sufficient to cause parametric four wave mixing and produce an optical comb.

In one embodiment, the dispersive material is silicon nitride.

In one embodiment, the cavity is a Fabry-Pérot (FP) cavity.

In one embodiment, the photonic crystal structure is chirped.

In one embodiment, a seed laser coupled to the optical cavity with an access waveguide.

In one embodiment, at least one mirror of the seed laser is a Bragg mirror coupled to the waveguide.

In one embodiment, at least one mirror of the seen laser at least one mirror of the seed laser is the end facet of chip coupled to the waveguide.

In one embodiment, the fabry perot is formed by a strip loaded waveguide with photonic crystal mirrors on each side.

In one embodiment, the strip loaded waveguide is comprised of layers of lithium niobate and silicon nitride.

The invention provides a means of creating a fabry perot comprised of one or more photonic crystals.

In another embodiment, there is provided a frequency comb laser device comprising:
a laser cavity having an optical gain material for coupling light to a waveguide comprising a dispersive material;
a reflector at the end of the gain material and a resonant mirror wherein the resonant mirror comprises a fabry perot cavity formed by one or more photonic crystal reflectors, such that lasing operation is sustained with the laser cavity.

### BRIEF DESCRIPTION OF THE DRAWINGS

The invention will be more clearly understood from the following description of an embodiment thereof, given by way of example only, with reference to the accompanying drawings, in which:—

FIG. 1 shows a first embodiment where a seed laser formed using a Bragg grating, wherein the seed laser is coupled to a Fabry-Perot (FP) cavity for frequency comb generation;

FIG. 2 shows as alternative embodiment, where the modes in the FP cavity are amplified within the gain media of a RSOA for comb formation;

FIG. 3 shows a schematic of a FP cavity which uses a photonic crystal (PhC) material for partial mirrors;

FIG. 4 shows a schematic of a Bragg mirror that acts as an external mirror;

FIG. 5A shows the spectral response of the FP cavity with PhC mirrors;

FIG. 5B shows an enlarged portion of the spectral response of the FP cavity with equidistant frequency modes; and

FIG. 6 illustrates a block diagram to show operation of the frequency comb laser device.

### DETAILED DESCRIPTION OF THE DRAWINGS

In order to overcome the problems with the prior art noted above, the present disclosure provides a laser cavity comprising a gain section, an on-chip waveguide and a photonic crystal (PhC) structure that acts as a reflector.

A photonic crystal is an optical device in which the refractive index has a periodic variation that affects the motion of photons of electromagnetic radiation by defining allowed and forbidden electromagnetic energy bands. Photons (behaving as electromagnetic waves) either propagate through this structure or not, depending on wavelength. Wavelengths that propagate are called modes, and groups of allowed modes form bands. Disallowed bands of wavelengths are called photonic band gaps.

The PhC structure is used as part to create a fabry perot cavity (also termed a standing wave optical resonator which is also referred in the art as a cavity) that may be coupled to a seed laser, or used as an intracavity element for a laser. As a result, it is possible to improve the control of the dispersion of a frequency comb source through the use of a PhC structure of the present disclosure in combination with or without other dispersion control mechanisms, such as e.g. waveguide geometry and/or material dispersion. The PhC structure can provide enhanced light-matter interactions and/or control over the number of frequency lines in the frequency comb (i.e. the number of different frequencies) that are produced. The PhC structure limits the number of modes supported by the fabry cavity to the desired number (determined by the target application).

Preferably, the Fabry-Perot cavity is based on an on-chip waveguide section (which are typically made of non-dispersive materials) with mirrors on each end that are comprised by a PhC structure (which is provides a dispersive and partially reflective material). Such cavities have densely spaced equidistant modes when made of non-dispersive materials. Since, in practice, the cavity is realised using a dispersive material, the modes may not be equidistant. However, these dispersive effects can be balanced by carefully chirping the PhC structure.

The on-chip waveguide of the PhC or laser cavity comprises a dispersive material, that has a large nonlinear refractive index. More preferably, stoichiometric silicon nitride (Si₃N₄) is used. Silicon Nitride is preferred as it can have a large non-linear coefficient. As disclosed in the paper entitled “Si-rich silicon nitride for nonlinear signal processing applications” by Lacava, C. et al, it is possible to obtain a nonlinear refractive index (n₂) of 2.4×10⁻¹⁹ m²/W using Silicon Nitride.

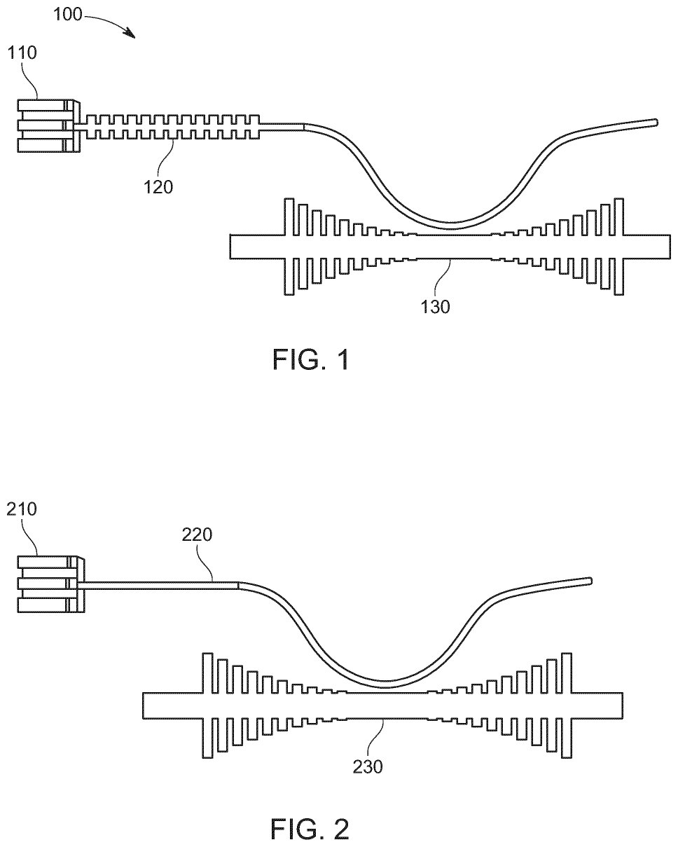

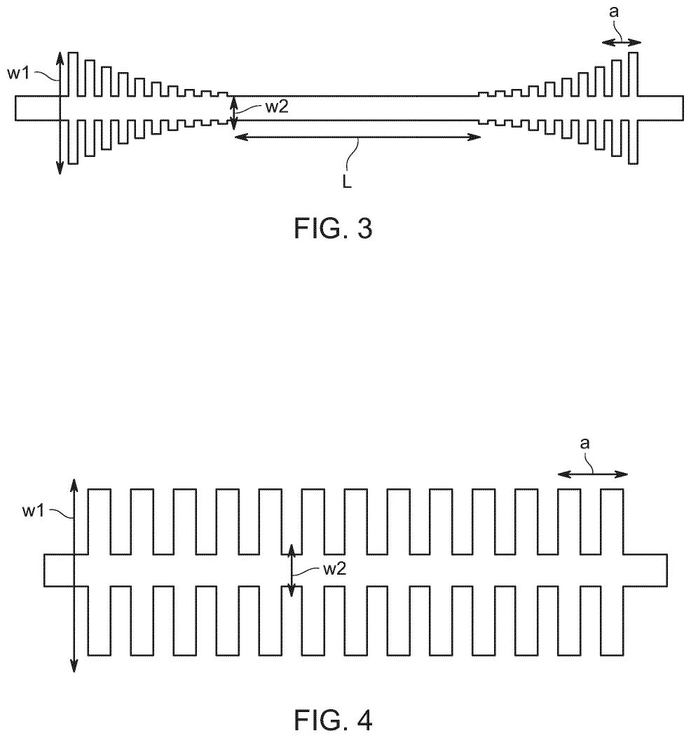

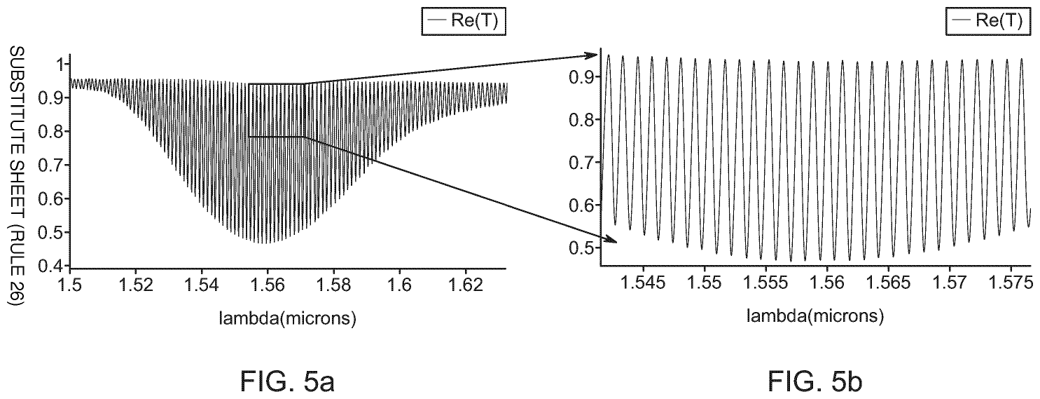

As shown in FIG. 1, in one embodiment in accordance with the present disclosure a seed laser 100 is formed using a Reflective Semiconductor Optical Amplifier (RSOA) 110 and a Bragg mirror 120. The resulting seed laser provides a narrow-line width output. The light from the seed laser is coupled to a Fabry-Perot (FP) cavity 130 via an access on-chip waveguide. The light coupled into the FP cavity 130 excites a four-wave mixing process in the SiₓN_{y} due to the strong non-linear effects of SiₓN_{y}. Photonic crystals mirrors are provided at the end of the FP cavity 130. The PhC bandwidth is finite and can be tailored by altering the parameters W1 and W2, which represent the widths of the sections forming the unit cell of the photonic crystal. W1, W2 are the lengths of the PhC mirrors, while a is the periodicity of the PhC mirrors. These are the geometric parameters of the PhC mirrors that control the reflection bandwidth of the PhCs. The number of the lines in the comb can be controlled via the bandwidth of the PhC. The comb lines supported will have higher power densities than those produced by other techniques in which the number of comb lines cannot be easily controlled and often is very large. Compared to other methods of generating an optical frequency comb (e.g. the micro-ring resonator), the photonic crystal provides more flexibility to customise the comb, for example limiting the number of lines supported and consequently increasing the optical power of each line.

On-chip waveguides are structures that are designed to guide and control the propagation of light on a chip or in an integrated circuit. They are typically made of materials such as silicon, silicon nitride or silicon dioxide and are formed using techniques such as etching or deposition. On the other hand, optical fibers are structures that are used to guide and control the propagation of light. They can be made from materials such as glass, plastic, and silicon, and can be formed using a variety of techniques, such as drawing, extrusion, etc.

The main difference between on-chip waveguides and optical fibers is that on-chip waveguides are integrated onto a chip or integrated circuit, while optical waveguides can be standalone structures. On-chip waveguides are typically smaller and more compact than standalone optical fibers, and offer the advantage of being able to integrate multiple functions onto a single chip, which can reduce cost and complexity.

The photonic crystals can be fabricated to allow selected modes to pass. The wavelengths which are not in a selected mode are reflected. The combination of the photonic crystals acting as a partial mirror and the four-wave mixing from the strong non-linear effects of the SiₓN_{y} results in the formation of a frequency comb. In the embodiment, the gain of the RSOA has no role in the formation of the frequency comb. Instead, the properties of the frequency comb depend on the balance between: i) dispersion and non-linearity effects of SiₓN_{y} waveguide; ii) the properties of the photonic crystals at the end of the FP cavity; and the iii) the bandwidth of the photonic crystal stopband.

In an alternative embodiment referred in FIG. 2, the seed laser cavity is formed using an RSOA 210, where the fabry perot cavity 230 acts as a resonant mirror. The FP cavity can be the same as the FP cavity 130 described above. The resonances of the FP cavity 130 provide feedback into the laser cavity. Due to the higher photonic density of states at resonances, preferential emission occurs at the modes of the FP cavity 130. When the optical power in the cavity is sufficient, one or more of the laser cavity modes that match an FP cavity mode reaches the lasing threshold. The lasing mode then acts as a pump for comb generation. In this embodiment, frequency comb generation is achieved by mode-locking based on dissipative driven four wave mixing. Again, photonic crystals are provided at the end of the FP cavity which have a stopband of a finite spectral width. Only modes within this spectral will contribute to the comb, limiting the number and increasing the power carried by each, which is desirable for applications. The photonic crystal parameters can be chosen so as to produce the number of comb lines suitable for the target application.

The combination of the photonic crystals acting as a partial mirror and the dissipative driven four wave mixing from the dispersive material results in the formation of a frequency comb. The FP cavity 130 acts as a resonant mirror and, like above, four wave mixing generates additional wavelengths that are phase locked to one another. The resulting modes are amplified by the RSOA. Frequency comb generation in this embodiment will occur at lower threshold powers than for the first design.

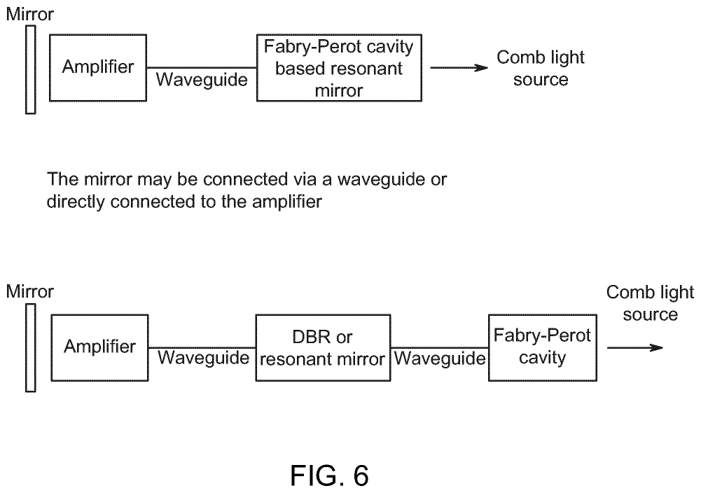

FIG. 6 illustrates a block diagram giving an outline of the design and operation of a frequency comb laser device according to the invention. A laser cavity having an optical gain material for coupling light to an on-chip waveguide comprising a dispersive material is provided. A reflector at the end of the optical gain material and a resonant mirror at the other; where the resonant mirror further comprises an on-chip waveguide coupled to a fabry perot cavity formed by one or more photonic crystal reflectors, such that lasing operation is sustained with the laser cavity. The lasing mode within the laser cavity can be configured to be in resonance with one of the modes supported by the fabry perot cavity, such that the light stored within the fabry-perot cavity comprises an optical density sufficient to cause parametric four wave mixing and produce an optical comb simply and effectively.

The exemplary embodiments set out above provide a FP cavity that yields high-Q longitudinal modes due to the highly reflecting photonic crystal structure (PhCs) at the end of the cavity. Coupling to the FP cavity from an on-chip waveguide provides a highly effective mechanism for exciting the modes of the FP cavity, which minimises losses. This configuration also operates as a resonant mirror providing the optical feedback into the RSOA required for lasing. The SiₓN_{y} nitride material system is preferred for these structures as it exhibits very low two photon absorption and a desirable third order susceptibility (χ⁽³⁾) coefficient.

Furthermore, the use of PhCs provides an extra lever for control of dispersion within the cavity. Further control can be provided by the selection of the on-chip waveguide parameters of the FP cavity and the dispersion provided by the SiₓN_{y} material.

In one embodiment, the fabry perot cavity is formed by a strip loaded on-chip waveguide comprised of layers of lithium niobate and silicon nitride with photonic crystal mirrors on each side. This configuration takes advantage of the strong nonlinear optical coefficients of lithium niobate, in particular the third order susceptibility (χ(3)) coefficient, and of the high refractive contrast and ease of processing of silicon nitride. The strip-loaded on-chip waveguide may be formed, for example, through the deposition of silicon nitride on Lithium Niobate on insulator or by micro transfer printing of lithium niobate onto a silicon nitride on-chip waveguide.

Those skilled in the art will note that the above examples and embodiments are provided as illustrative examples and are the above description is not intended to limit the scope of the present disclosure. Instead, the scope of the present disclosure is defined by the appended claims.

In the specification the terms “comprise, comprises, comprised and comprising” or any variation thereof and the terms include, includes, included and including” or any variation thereof are considered to be totally interchangeable, and they should all be afforded the widest possible interpretation and vice versa.

The invention is not limited to the embodiments hereinbefore described but May be varied in both construction and detail.

1. A frequency comb laser device comprising:
a laser cavity having an optical gain material for coupling light to a waveguide comprising a dispersive material; and
a reflector at the end of the optical gain material and a resonant mirror at the other, wherein the resonant mirror comprises an on-chip waveguide coupled to a fabry perot cavity formed by one or more photonic crystal reflectors, such that lasing operation is sustained with the laser cavity.

2. The device of claim 1 wherein a lasing mode within the laser cavity is configured to be in resonance with one of the modes supported by the fabry perot cavity, such that the light stored within the fabry-perot cavity comprises an optical density sufficient to cause parametric four wave mixing and produce an optical comb.

3. The device of claim 1 or 2 in which the parameters of the photonic crystal are selected to limit the number of lines in the comb to the desired number.

4. The device of any preceding claim, wherein the dispersive material is silicon nitride.

5. The device of any preceding claim, wherein the fabry perot cavity is designed to balance the dispersion of the supported modes

6. The device of any preceding claim, wherein the photonic crystal structure is chirped.

7. The device of any preceding claim wherein a seed laser is coupled to the fabry perot cavity to generate an optical comb.

8. The device of any preceding claim, wherein the fabry perot cavity is formed by a strip loaded waveguide with photonic crystal mirrors on each side.

9. The device of any preceding claim, wherein the strip loaded waveguide is comprised of layers of lithium niobate and silicon nitride.
